(19) United States
(12) Patent Application Publication
(10) Pub. No.: US 2020/0058840 A1
(43) Pub. Date: Feb. 20, 2020

(54) OPTOELECTRONIC SEMICONDUCTOR CHIP AND METHOD OF PRODUCING AN OPTOELECTRONIC SEMICONDUCTOR CHIP

(71) Applicant: OSRAM Opto Semiconductors GmbH, Regensburg (DE)

(72) Inventors: Ivar Tångring, Regensburg (DE); Christian Leirer, Friedberg (DE)

(21) Appl. No.: 16/603,007

(22) PCT Filed: May 2, 2018
(86) PCT No.: PCT/EP2018/061160

§ 371 Date: Oct. 4, 2019

(30) Foreign Application Priority Data
May 3, 2017 (DE) 10 2017 109 485.7

(51) Int. Cl. H01L 33/64; H01L 33/50; H01L 33/62; H01L 33/48; H01L 33/00

(52) U.S. Cl. CPC H01L 33/641; H01L 33/502; H01L 33/644; H01L 2933/0075; H01L 33/486; H01L 33/0079; H01L 2933/0041; H01L 33/62

(57) ABSTRACT

An optoelectronic semiconductor chip includes a semiconductor layer sequence having an active layer that generates electromagnetic radiation, two contact elements on a back side of the semiconductor layer sequence, a radiolucent cooling element on a front side of the semiconductor layer sequence opposite the back side, and a siloxane-containing converter layer between the cooling element and the semiconductor layer sequence, wherein the contact elements are configured for electrical contacting of the semiconductor chip and are exposed in the unmounted state of the semiconductor chip, the cooling element is different from a growth substrate of the semiconductor layer sequence, and the cooling element has a thermal conductivity of at least 0.7 W/(m·K).

### TECHNICAL FIELD

This disclosure relates to an optoelectronic semiconductor chip and a method of manufacturing an optoelectronic semiconductor chip.

### BACKGROUND

There is a need for an optoelectronic semiconductor chip with efficient heat dissipation and a method of manufacturing such a semiconductor chip.

### SUMMARY

We provide an optoelectronic semiconductor chip including a semiconductor layer sequence having an active layer that generates electromagnetic radiation, two contact elements on a back side of the semiconductor layer sequence, a radiolucent cooling element on a front side of the semiconductor layer sequence opposite the back side, and a siloxane-containing converter layer between the cooling element and the semiconductor layer sequence, wherein the contact elements are configured for electrical contacting of the semiconductor chip and are exposed in the unmounted state of the semiconductor chip, the cooling element is different from a growth substrate of the semiconductor layer sequence, and the cooling element has a thermal conductivity of at least 0.7 W/(m·K).

We also provide a method of manufacturing an optoelectronic semiconductor chip including A) growing a semiconductor layer sequence having an active layer on a growth substrate; B) applying contact elements to a back side of the semiconductor layer sequence facing away from the growth substrate; C) depositing the semiconductor layer sequence on an auxiliary carrier; D) removing the growth substrate; E) applying a converter layer to a front side of the semiconductor layer sequence opposite the back side, wherein the converter layer includes siloxane; F) applying a radiolucent cooling element to the front side of the semiconductor layer sequence, wherein the cooling element has a thermal conductivity of at least 0.7 W/(m·K), and G) removing the auxiliary carrier.

We further provide an optoelectronic semiconductor chip including a semiconductor layer sequence having an active layer that generates electromagnetic radiation, two contact elements on a back side of the semiconductor layer sequence, a radiolucent cooling element on a front side of the semiconductor layer sequence opposite the back side, and a siloxane-containing converter layer between the cooling element and the semiconductor layer sequence, wherein the contact elements are configured for electrical contacting of the semiconductor chip and are exposed in the unmounted state of the semiconductor chip, the cooling element is different from a growth substrate of the semiconductor layer sequence, the cooling element has a thermal conductivity of at least 0.7 W/(m·K), and the cooling element is self-supporting.

### BRIEF DESCRIPTION OF THE DRAWINGS

FIGS. 1A to 1F show different positions in an example of a method of manufacturing an optoelectronic semiconductor chip.

FIGS. 2A to 2E show various examples of an optoelectronic semiconductor chip in cross-sectional view.

### REFERENCE NUMBER LIST

1 semiconductor layer sequence

3 cooling element

4 converter layer

5 carrier

10 active layer

11 front side

12 back side

13 first layer

14 second layer

21 first contact element

22 second contact element

23 potting

4 adhesive layer

100 optoelectronic semiconductor chip

### DETAILED DESCRIPTION

Our optoelectronic semiconductor chip may comprise a semiconductor layer sequence having an active layer that generates electromagnetic radiation. The semiconductor layer sequence, for example, is based on a III-V compound semiconductor material. For example, the semiconductor material is a nitride compound semiconductor material such as AlₙIn₁₋ₙ₋ₘGaₘN, or a phosphide compound semiconductor material such as AlₙIn₁₋ₙ₋ₘGaₘP, or an arsenide compound semiconductor material such as AlₙIn₁₋ₙ₋ₘGaₘAs or AlₙIn₁₋ₙ₋ₘGaₘAsP, wherein in each example 0≤n≤1, 0≤m≤1 and m+n≤1. The semiconductor layer sequence may contain dopants as well as additional components. For the sake of simplicity, however, only the essential components of the crystal lattice of the semiconductor layer sequence, i.e. Al, As, Ga, In, N or P, are specified, even if they may be partially replaced and/or supplemented by small quantities of other substances. The semiconductor layer sequence is preferably based on AlInGaN.

The active layer of the semiconductor layer sequence contains in particular at least one pn junction and/or at least one quantum well structure and may, for example, generate electromagnetic radiation in the blue or green or red spectral range or in the UV range during intended operation. Preferably, the semiconductor chip comprises one, in particular exactly one, continuous active layer.

The semiconductor chip may comprise two or more contact elements on a back side of the semiconductor layer sequence. The contact elements are particularly metallic. For example, the contact elements comprise silver, copper, nickel, gold, titanium, palladium or consist of one of these materials or a mixture of these materials.

The semiconductor chip may comprise a radiolucent cooling element on a front side of the semiconductor layer sequence opposite the back side. For example, the cooling element completely covers the semiconductor layer sequence in plan view, i.e. it covers the entire front side of the semiconductor layer sequence. Preferably, the cooling element only covers the front side of the semiconductor layer sequence.

The cooling element may be transparent, i.e. image permeable or view permeable, or translucent for electromagnetic radiation generated by the active layer. In other words, the cooling element can be transparent or milky turbid.

The cooling element is particularly preferably transparent or translucent for such electromagnetic radiation that strikes the cooling element from the direction of the active layer. This radiation may be the primary radiation generated directly by the active layer and/or secondary radiation generated by conversion from the primary radiation. For example, the transparency of the cooling element is at least 80% or at least 90% or at least 95% or at least 99% for radiation coming from the direction of the active layer.

The cooling element may be in the form of a platelet with two substantially parallel main sides, the main sides being substantially parallel to the front side of the semiconductor layer sequence. However, the cooling element can also have a curved main side on a side facing away from the semiconductor layer sequence. In this example, the cooling element is designed as a lens, for example. Furthermore, the cooling element can be designed in one piece or can be composed of several different individual layers. However, the material composition of the cooling element is preferred to be homogeneous over the entire volume of the cooling element.

For example, the front side and/or the back side border directly on the semiconductor layer sequence. In particular, the front side and/or the back side are formed from the semiconductor material of the semiconductor layer sequence. The front side and back side are essentially parallel to each other and to the active layer.

The semiconductor chip may comprise a siloxane-containing converter layer between the cooling element and the semiconductor layer sequence. The siloxane or siloxanes of the converter layer are preferably polysiloxanes or polysiloxanes such as silicone.

The converter layer is preferably based on siloxane. For example, the siloxane content in the converter layer is at least 60 vol. % or at least 70 vol. % or at least 80 vol. % or at least 90 vol. %. For example, the converter layer comprises or consists of a siloxane matrix with converter particles embedded therein. The concentration of converter particles in the converter layer, for example, is at least 10 vol. % or at least 20 vol. %. Alternatively or additionally, the concentration of the converter particles in the converter layer is, for example, not more than 40 vol. % or not more than 30 vol. %. For example, the converter layer is formed in one piece. For example, the material composition of the converter layer is homogeneous over its entire volume. In particular, the converter layer is only formed by a single layer and not by superimposed individual layers. Alternatively, the converter layer can also be composed of several adjacent individual layers, wherein each of the individual layers, for example, comprises or is based on siloxane.

The converter layer, for example, has a thickness, measured perpendicular to the front side of the semiconductor layer sequence, of at least 30 μm or at least 40 μm or at least 50 μm. Alternatively or additionally, the thickness of the converter layer may, for example, be not more than 80 μm or not more than 70 μm or not more than 60 μm.

The converter layer is preferably arranged only on the front side of the semiconductor layer sequence. In particular, the converter layer completely covers the front side of the semiconductor layer sequence. The converter layer can be in direct contact with the front side or the semiconductor material of the semiconductor layer sequence.

The converter layer converts all or part of the primary radiation generated by the active layer into secondary radiation with a longer wavelength when the semiconductor chip is operated as intended. For example, the converter layer converts a blue primary radiation generated by the active layer into yellow or green or red secondary radiation in whole or in part. The radiation emerging from the converter layer can therefore be a mixture of primary and secondary radiation or be formed exclusively from secondary radiation. The radiation emitted from the converter layer and from the semiconductor chip is preferably visible light such as white light.

The contact elements may be configured for electrical contacting of the semiconductor chip or the semiconductor layer sequence and are exposed in the unmounted state of the semiconductor chip, for example on an underside of the semiconductor chip. In particular, the semiconductor chip can therefore be a surface-mountable semiconductor chip. The semiconductor chip can, for example, be mounted on a connection board. There are preferably no contact elements on the front side of the semiconductor chip.

The cooling element may be different from a growth substrate of the semiconductor layer sequence. In particular, the growth substrate on which the semiconductor layer sequence, for example, was epitaxially grown, is ablated or removed from the semiconductor chip. The semiconductor chip is preferably free of the growth substrate.

The cooling element may have a thermal conductivity of at least 0.7 W/(m·K) or at least 0.8 W/(m·K) or at least 0.9 W/(m·K) or at least 1.0 W/(m·K). Thermal conductivity means in particular the thermal conductivity averaged over the entire cooling element.

The distance between the converter layer and the cooling element need not be more than 10 μm or not more than 8 μm or not more than 5 μm or not more than 3 μm. The distance is preferably the maximum or mean distance along the entire lateral extent of the semiconductor chip. The distance is measured in particular in the direction perpendicular to the front side.

In addition, an optoelectronic semiconductor chip is a component produced from a wafer composite by separation. This may mean that the lateral dimensions of the semiconductor chip essentially correspond to the lateral dimensions of the active layer of the semiconductor layer sequence. For example, the lateral dimension of the semiconductor chip is not more than 10% or not more than 5% or not more than 1% larger than the lateral dimension of the active layer. The lateral direction in which the lateral dimension is determined is a direction parallel to the main extension direction of the active layer. The optoelectronic semiconductor chip is preferably self-supporting. In other words, it can be a so-called chip-size package, CSP for short so that at least the lateral size of the semiconductor chip is essentially determined by the semiconductor layer sequence. The potting and the contact elements therefore do not contribute significantly to the lateral size.

The optoelectronic semiconductor chip may comprise a semiconductor layer sequence having an active layer that emits electromagnetic radiation. The semiconductor chip further comprises two contact elements on a back side of the semiconductor layer sequence and a radiolucent cooling element on a front side of the semiconductor layer sequence opposite the back side. A siloxane-containing converter layer is arranged between the cooling element and the semiconductor layer sequence. The contact elements are configured for electrical contacting of the semiconductor chip and are exposed in the unmounted state of the semiconductor chip. The cooling element is different from a growth substrate of the semiconductor layer sequence and has a thermal conductivity of at least 0.7 W/(m·K).

Our chips and methods are based in particular on the knowledge that siloxane-based, especially silicone-based, converter layers are frequently used for converter layers in optoelectronic semiconductor chips, partly because these have a high refractive index. However, these converter layers have the disadvantage that they have a low thermal conductivity of 0.2 to 0.3 W/(m·K) or less, for example, 0.16 to 0.25 W/(m·K). The heat generated by the converter particles embedded in the siloxane during the conversion of light can therefore only be dissipated poorly from the converter layer. This leads to a strong warming of the converter layer during operation, especially on its outer surfaces, which causes the converter layer to rapidly age, which can be seen, for example, in crack formation. A further disadvantage of the siloxane-containing converter layer is that it is sticky so that unwanted particles can stick to an exposed converter layer.

We make use of the idea of placing a radiolucent cooling element on the converter layer. Even a low thermal conductivity of 0.7 W/(m·K) can be sufficient to greatly improve the thermal properties of the entire semiconductor chip. The distance between the converter layer and the cooling element is preferably chosen to be small to improve this effect, resulting in efficient heat transfer from the converter layer to the cooling element. Furthermore, the radiolucent cooling element covers the sticky surface of the converter layer and prevents unwanted particles from sticking.

The cooling element may comprise glass or consist of glass, in particular high refractive glass. In particular, the cooling element may be a glass substrate or a glass plate. The glass can be quartz glass, borosilicate glass, flint glass or lead crystal glass. Glass also has the advantage that, in contrast to the converter layer, it has a comparatively high modulus of elasticity. Normally, when the semiconductor chip heats up, the converter layer expands relatively strongly, which, as mentioned above, can lead to cracks in the converter layer over time. With its high modulus of elasticity, a glassy cooling element applied to the converter layer ensures that the converter element can hardly expand so that the entire semiconductor chip becomes more stable to ageing.

Alternatively, it is also possible to choose sapphire or plastic as the material for the cooling element instead of glass.

A mechanical connection, for example an adhesive layer, between the cooling element and the converter layer may be chosen so that the cooling element is permanently bonded to the converter layer. It is, for example, a material-locking connection between the cooling element and the converter layer. The cooling element may be connected to the converter layer in a non-destructively detachable way. During the intended operation, i.e. at normal forces and accelerations, the cooling element preferably does not separate from the converter layer. For example, the connection is so strong that the cooling element prevents or restricts lateral thermal expansion of the converter layer. In particular, the connection is chosen so strong that the connection is not completely or not locally loosened, i.e. at certain points, by the lateral forces occurring during the intended operation due to heating.

The cooling element may be self-supporting. For example, the cooling element is then one or the only supporting component in the semiconductor chip. For example, there is no other self-supporting element in the semiconductor chip. For example, the cooling element carries the semiconductor layer sequence and the contact elements.

The thickness of the cooling element may be at least 250 μm or at least 300 μm or at least 400 μm. Especially with such a thickness and typical lateral expansion of semiconductor chips of 5 mm or less, such a cooling element can be self-supporting.

The distance between the back side of the semiconductor layer sequence and the sides of the contact elements exposed in the unmounted state or the underside of the semiconductor chip may be at most 5 μm or at most 3 μm or at most 2 μm. In particular, there is no supporting component of the semiconductor chip on the back side.

A carrier may be arranged on the back side of the semiconductor layer sequence. The carrier can be formed, for example, by the contact elements and an insulation between them such as a polymer potting, epoxy potting or silicone potting. In particular, the carrier is self-supporting. For example, the carrier on the back side is one or the only mechanically stabilizing component in the semiconductor chip that carries the semiconductor chip. In this example, the cooling element is not self-supporting and alone cannot guarantee the stability of the semiconductor chip.

The thickness of the cooling element may be at most 100 μm or at most 50 μm or at most 30 μm or at most 10 μm. In these examples, the cooling element is not self-supporting. However, even a thickness as small as 10 μm, for example, is sufficient to partially compensate for the poor thermal conductivity of the converter layer. However, preferably, the thickness of the cooling element is at least 5 μm.

The contact elements on the back side may have a thickness of at least 100 μm or at least 120 μm. For example, the contact elements are applied galvanically to the semiconductor layer sequence. In this example, the contact elements form part of a carrier on the back side of the semiconductor layer sequence.

The cooling element may form a radiation exit surface of the semiconductor chip. For example, at least 80% or at least 90% or at least 95% of the radiation emitted from the semiconductor chip is decoupled via the cooling element. The cooling element can be directly adjacent to an ambient gas such as air.

The converter layer may comprise a silicone matrix with converter particles embedded therein or consists of a silicone matrix with converter particles embedded therein. Silicone is a preferred siloxane for use in converter layers.

The converter particles may comprise particles having the structural formula A₃B₅O₁₂:Ce³⁺ where A=Lu, Y or Tb and B=A or Ga, and/or (Ca,Sr)AlSiN₃:Eu²⁺, and/or Sr(Ca,Sr)Si₂Al₂N₆:Eu²⁺, and/or (Ca,Ba,Sr)₂Si₅N₈:Eu²⁺, and/or Sr₄Al₁₄O₂₅:Eu²⁺, and/or EuₓSi_{6-z}Al_{z}O_{z}N_{8-z}, and/or MₓSi₁₂₋ₘ₋ₙAlₘ₊ₙOₙN₁₆₋ₙ:Eu²⁺ and/or M₂SiO₄:Eu²⁺ with M=Ba, Sr, Ca or Mg, and/or K₂SiF₆:Mn⁴⁺, and/or MSi₂N₂O₂:Eu²⁺ with M=Ba, Sr or Ca. Other types of converter particles are also possible.

A radiolucent adhesive layer may be arranged between the converter layer and the cooling element. For example, the adhesive layer has a thickness of at most 10 μm or at most 8 μm or at most 5 μm or at most 3 μm. For example, the adhesive layer is made of silicone or comprises silicone. The adhesive layer may be transparent or translucent, especially for primary and/or secondary radiation. The adhesive layer is preferably in direct contact with both the converter layer and the cooling element.

The adhesive layer serves in particular to reliably attach the cooling element to the converter layer or to the semiconductor layer sequence.

The adhesive layer may have a matrix such as a silicone matrix, with filling particles embedded therein that are transparent to the primary and/or secondary radiation. The filling particles particularly preferably have a higher thermal conductivity than the matrix material of the adhesive layer, for example, a thermal conductivity at least twice as high as the matrix material of the adhesive layer. This further improves the thermal coupling of the converter layer to the cooling element.

The converter layer may be in direct contact with the cooling element. In other words, between the converter layer and the cooling element there is no other layer like an adhesive layer. For example, the cooling element is applied directly to the converter layer. The direct contact between the converter layer and the cooling element is particularly advantageous with regard to the thermal coupling.

The semiconductor layer sequence may be structured at the front side. In particular, the semiconductor layer sequence is structured such that the total reflection of electromagnetic radiation at the front side is reduced and thus the decoupling efficiency from the semiconductor layer sequence is increased.

The contact elements may be laterally partially or completely surrounded by a potting, in particular an electrically insulating potting. Lateral means that the contact elements are surrounded by the potting in a lateral direction, i.e. parallel to a main direction of extension of the active layer. The contact elements can terminate flush with the potting on an underside of the semiconductor chip. Alternatively, it is also possible that the potting does not extend to the underside of the semiconductor chip and, for example, laterally only covers up to half of the contact elements. The contact elements then protrude from the potting. The potting can be a polymer or an epoxy or a silicone, for example. Together with the contact elements, the potting can form a carrier that stabilizes the semiconductor chip.

The cooling element may have one or more functional layers. For example, the cooling element comprises a dielectric mirror layer and/or a Bragg mirror and/or a conversion layer. In particular, the cooling element can further influence the radiation characteristics of the semiconductor chip in this way.

The cooling element, which is in particular made of glass, may serve primarily as a carrier for the mechanical reinforcement of the converter layer and/or the semiconductor chip and only secondarily for cooling the converter layer and/or the semiconductor layer sequence. There is a certain redistribution of heat due to the cooling element, but this effect can be comparatively small since there is no thermally highly conductive heat conduction path from the cooling element to the contact elements. For example, the cooling element contributes to a cooling of the converter layer and/or the semiconductor layer sequence to a maximum of 50% or 20% or 10%, whereby a main cooling can be done via the contact elements to a mounting surface of the semiconductor chip and then further to an external heat sink.

We also provide a method of manufacturing an optoelectronic semiconductor chip. The method is particularly suitable for manufacturing a semiconductor chip as described above. This means that all features disclosed in connection with the semiconductor chip are also disclosed for the method and vice versa.

The method may comprise a step A) in which a semiconductor layer sequence having an active layer is grown on a growth substrate.

The method may comprise a step B) in which contact elements are applied to a back side of the semiconductor layer sequence facing away from the growth substrate.

The semiconductor layer sequence may be applied to an auxiliary carrier in a step C). For example, the semiconductor layer sequence is applied with the contact elements first to an auxiliary carrier.

The growth substrate may be removed in a step D). For example, the growth substrate is removed by a laser lift-off process.

In a step E) a converter layer may be applied to a front side of the semiconductor layer sequence opposite to the back side. The converter layer may comprise siloxane.

A radiolucent cooling element may be applied to the front side of the semiconductor layer sequence in a step F). The cooling element may have a thermal conductivity of at least 0.7 W/(m·K). The distance between the converter layer and the cooling element is set, for example, to at most of 10 μm.

The auxiliary carrier may be removed in a step G).

The method preferably includes a further step H) in which the semiconductor layer sequence with the cooling element is cut or sawn or diced into individual semiconductor chips. In particular, a large-area cooling element and a large-area semiconductor layer sequence form a wafer composite during the manufacturing method. The large-area cooling element and the large-area semiconductor layer sequence are then divided into individual cooling elements and individual semiconductor layer sequences for each individual semiconductor chip. The cooling element of each individual semiconductor chip can therefore show traces of material removal, especially on side surfaces.

Steps A) to H) may be performed one after the other in the specified order.

The converter layer may be applied to the semiconductor layer sequence by spray coating.

The cooling element may be applied to an undried converter layer so that the converter layer serves as an adhesive for the cooling element. If the converter layer is applied by spray coating, for example, it is initially liquid and sticky. This is used to fix the cooling element to the converter layer without the need for a further adhesive layer.

The cooling element may be a glass layer applied by evaporation. This makes it possible to produce a particularly thin layer of glass, which then serves as a cooling element.

The converter layer need not be structured, but applied over the entire surface and/or continuously, preferably in a chip wafer composite. This leads in particular to the fact that there are no side walls around the converter layer. Thus, the converter layer is exposed on the side surfaces of the individual semiconductor chips. In lateral direction, the converter layer can terminate flush the cooling element.

The separation to the semiconductor chips, also referred to as separation or splitting, may take place in a single, common step. This means that the cooling element, the converter layer, the potting, the contact elements and the insulation layers are cut through in a single step. Separation takes place, for example, by sawing or laser irradiation.

Separation may be carried out by sawing, in particular in a single sawing step and/or with a single saw blade. Saw traces are preferably narrow, typically not more than 100 μm wide, preferably not more than 50 μm wide. For example, the width of the saw trace is 20 μm to 50 μm.

The growth substrate may be removed from the semiconductor layer sequence. This allows a lower thermal resistance of the semiconductor chip. The growth substrate is preferably removed before the converter layer and the cooling element are applied to the semiconductor layer sequence, but can also be removed afterwards. When removing the growth substrate, the semiconductor layer sequence is preferably located on a temporary auxiliary carrier. In particular by removing the growth substrate, it is possible to connect the complete chip wafer with preferably a single glass wafer for the cooling elements and also as a carrier so that the growth substrate can be removed as a complete wafer and the arrangement can still be handled as a wafer afterwards.

In the following, an optoelectronic semiconductor chip described herein as well as a method of manufacturing an optoelectronic semiconductor chip described herein is explained in more detail with reference to drawings on the basis of examples. Same reference signs indicate the same elements in the individual figures. However, the size ratios involved are not to scale, individual elements may rather be illustrated with an exaggerated size for a better understanding.

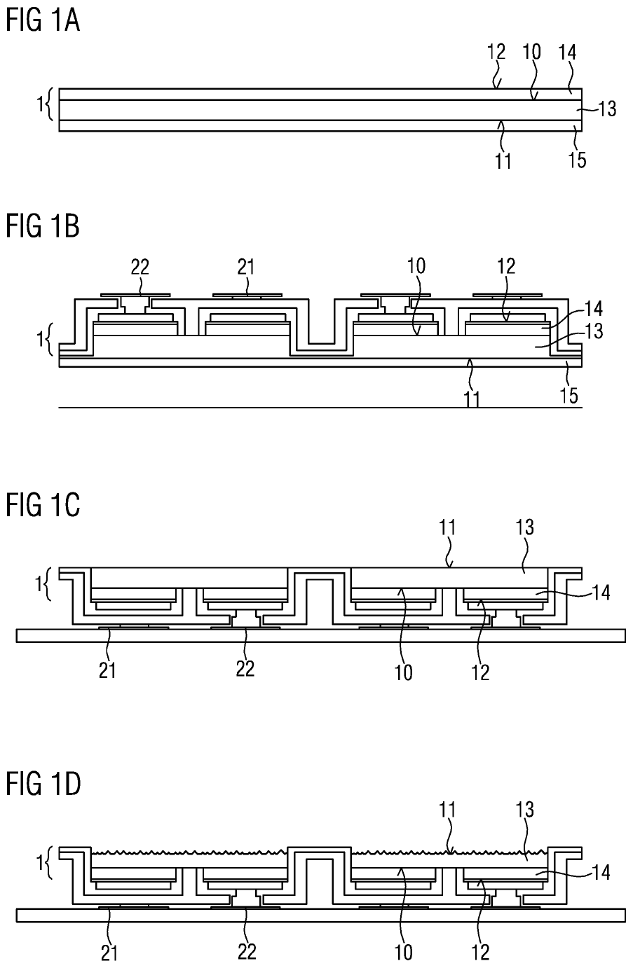

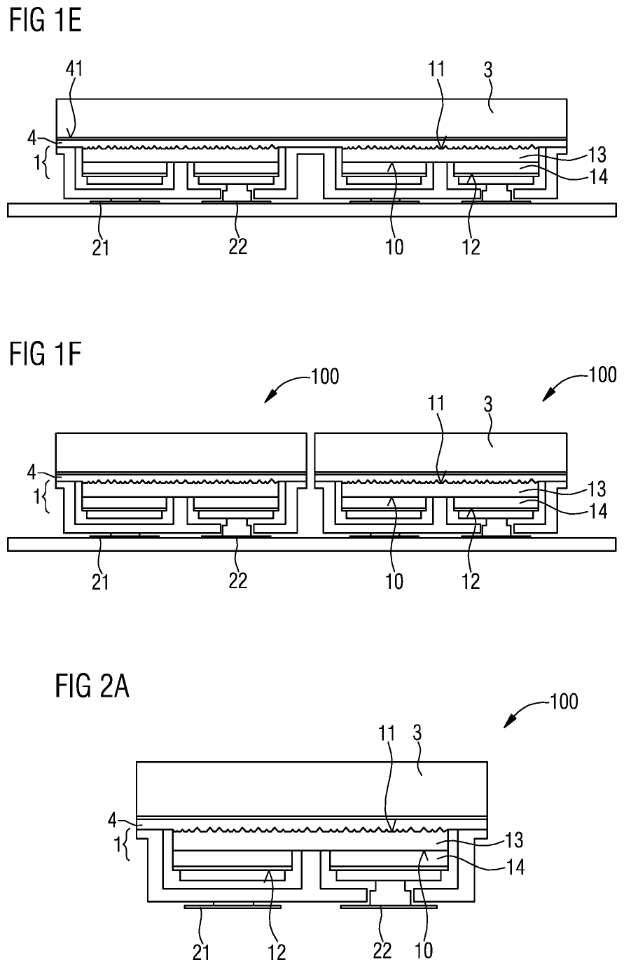

FIG. 1A shows a position in an example of a method of manufacturing an optoelectronic semiconductor chip 100. A semiconductor layer sequence 1 has grown on a growth substrate 15, for example, a sapphire substrate. The semiconductor layer sequence 1, for example, is based on GaN. It comprises a first layer 13 that is, for example, an n-conductive layer, a second layer 14 that is, for example, a p-conductive layer, and an active layer 10 between the first layer 13 and the second layer 14. The active layer 10 is intended to generate electromagnetic radiation during intended operation. The side of the semiconductor layer sequence 1 adjacent to the growth substrate 15 forms a front side 11 of the semiconductor layer sequence 1, the opposite side of the semiconductor layer sequence 1 forms a back side 12.

FIG. 1B shows a position in the method at a later point in time. Contact elements 21, 22 that are electrically isolated from each other by insulation layers, are applied to the back side 12 of the semiconductor layer sequence 1. A respective second contact element 22 electrically conductively connects to the second layer 14, a respective first contact element 21 electrically conductively connects to the first layer 13 via a through connection extending through the second layer 14 and the active layer 10 into the first layer 13.

In the position of the method shown in FIG. 1C, the semiconductor layer sequence 1 is applied to an auxiliary carrier with the contact elements 21, 22 first. The auxiliary carrier serves for the temporary stabilization of the semiconductor layer sequence 1.

In addition, FIG. 1C shows that the growth substrate 15 is detached from the semiconductor layer sequence 1. This can be done, for example, by a laser lift-off process. The front side 11 of the semiconductor layer sequence 1 is therefore exposed in FIG. 1C.

FIG. 1D shows a position in the method after the front side 11 of the semiconductor layer sequence 1 has been structured or roughened. This can be done, for example, by an etching process. The structuring or roughening of the semiconductor layer sequence 1 on the front side 11 results in a more efficient radiation decoupling from the semiconductor layer sequence 1.

FIG. 1E shows a position in the method after first applying a converter layer 4, then an adhesive layer 41 and then a radiolucent cooling element 3 to the front side 11 of the semiconductor layer sequence 1. The converter layer 4 comprises a siloxane such as silicone. For example, the converter layer 4 is a silicone matrix with converter particles embedded in it. The converter layer 4 converts part or all of the electromagnetic primary radiation generated by the active layer 10 into secondary radiation of a different wavelength during intended operation. The converter layer 4, for example, has a thickness of 40 μm to 60 μm.

The adhesive layer 41, for example, can be a transparent silicone layer. The thickness of the adhesive layer 41, for example, is 3 μm to 8 μm.

The adhesive layer 41 connects the semiconductor layer sequence 1 or the converter layer 4 with the radiolucent cooling element 3. Alternatively, the adhesive layer 41 can be omitted so that the cooling element 3 is in direct contact with the converter layer 4.

The cooling element 3 is, for example, a glass layer or a glass platelet or a glass substrate. The cooling element 3, for example, is transparent for the primary and secondary radiation coming from the semiconductor layer sequence 1.

FIG. 1E shows an example of a self-supporting cooling element 3 with a thickness of at least 250 μm. In particular, the cooling element 3 of FIG. 1E is a glass platelet. In contrast to FIG. 1E, the cooling element 3 can also be designed as a very thin glass layer, for example, with a thickness of at most 50 μm. Such a glass layer, for example, would not be self-supporting.

FIG. 1F shows another position in the process after singulating the wafer composite of the cooling element 3 and the semiconductor layer sequence 1. This produces individual semiconductor chips 100, which are still attached to the auxiliary carrier. The auxiliary carrier can then be removed.

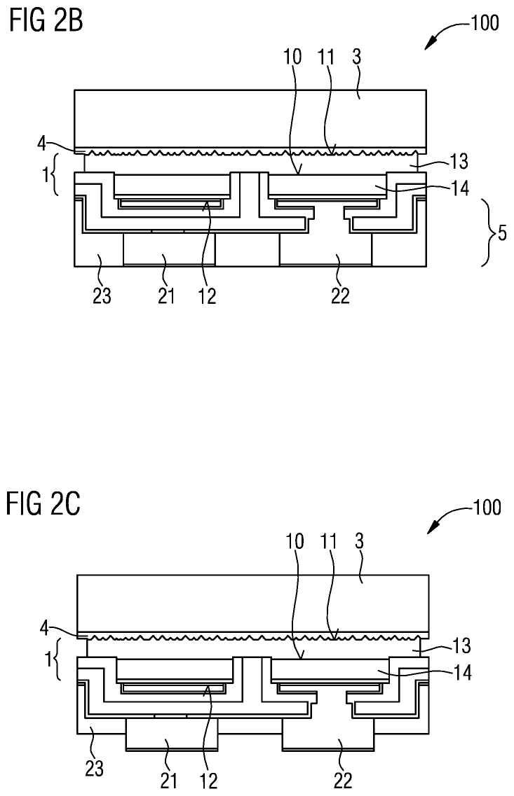

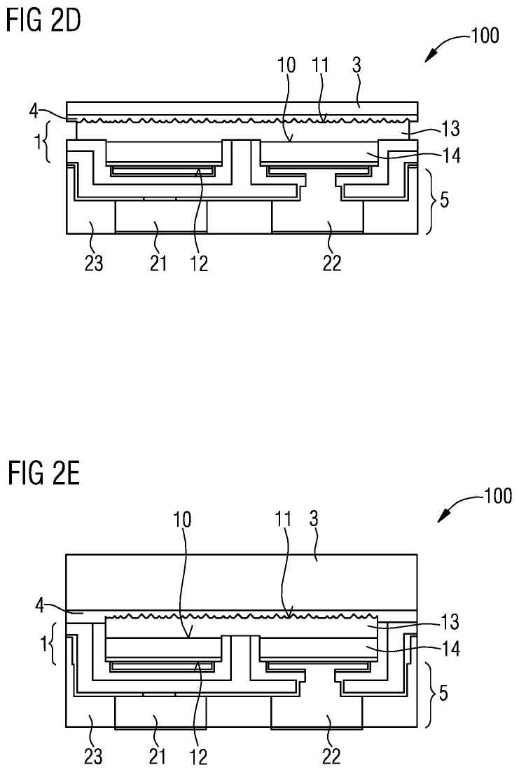

FIG. 2A shows an example of a semiconductor chip 100 in cross-sectional view. The semiconductor chip 100 of FIG. 2A, for example, is manufactured by the process or method of FIGS. 1A to 1F. In FIG. 2A, the cooling element 3 is self-supporting and forms the supporting component of the semiconductor chip 100. This means that the cooling element 3 alone carries and stabilizes the semiconductor layer sequence 1 and the contact elements 21, 22. Without the cooling element 3, the semiconductor chip 100 would not be mechanically self-supporting. The contact elements 21, 22 in FIG. 2A, for example, have a thickness of at most 5 μm. The distance between the back side 12 of the semiconductor layer sequence 1 and the sides of the contact elements 21, 22 facing away from the semiconductor layer sequence 1, for example, is also at most 5 μm.

FIG. 2B shows another example of a semiconductor chip 100 in cross-sectional view. In contrast to FIG. 2A, the contact elements 21, 22 are now much thicker, for example, with a thickness of at least 100 μm. The contact elements 21, 22, for example, are applied using a galvanic process. A potting 23 is arranged around the contact elements 21, 22. The potting 23 can be, for example, a polymer or an epoxy or a silicone. In this example, the potting 23 and the contact elements 21, 22 form an underside of the semiconductor chip 100, which is exposed in the unmounted state. The potting 23 and the contact elements 21, 22 are terminate flush with each other at the underside. The potting 23 completely surrounds the contact elements 21, 22 laterally, i.e. in the lateral direction.

In FIG. 2B, the potting 23 together with the contact elements 21, 22 forms a carrier 5 on the back side 12 of the semiconductor layer sequence 1. This carrier 5, for example, is self-supporting. The carrier 5 can mechanically stabilize and carry the semiconductor layer sequence 1. In this example, the cooling element 3 can still be self-supporting, but the cooling element 3 can also not be self-supporting.

The example of FIG. 2C shows a semiconductor chip 100 essentially corresponding to the semiconductor chip 100 of FIG. 2B. In contrast to FIG. 2B, however, the potting 23 does not completely laterally surround the contact elements 21, 22. In particular, the potting 23 does not terminate flush with the contact elements 21, 22 on an underside of the semiconductor chip 100. Instead, the contact elements 21, 22 are only partially laterally surrounded by the potting 23. For example, the thickness of the potting 23 on the back side 12 of semiconductor layer sequence 1 is at most only half as thick as that of the contact elements 21, 22.

In the example of FIG. 2C, for example, the contact elements 21, 22 together with potting 23 do not form a mechanically stable carrier. In this example, the semiconductor layer sequence 1 or the semiconductor chip 100 is stabilized and supported by the mechanically self-supporting cooling element 3. However, it is also possible that the contact elements 21, 22 and the potting 23 in FIG. 2C support the stability of the semiconductor chip 100 or cause the stability.

The semiconductor chip 100 of FIG. 2C is characterized in particular by the fact that the different coefficients of expansion of the different materials are compensated. In particular, the semiconductor layer sequence 1 usually has a different coefficient of thermal expansion than a connection board on which the semiconductor chip 100 is mounted. This difference in the thermal expansion coefficient is partially compensated by the thick contact elements 21, 22 and the potting 23 arranged between them so that less stress occurs within the semiconductor layer sequence 1 during operation, which reduces the risk of cracks in the semiconductor layer sequence 1.

FIG. 2D shows an example of a semiconductor chip 100 in which the encapsulation 23 together with the contact elements 21, 22 form a carrier 5 stabilizing the semiconductor layer sequence 1 or the semiconductor chip 100. The cooling element 3 on the front side 11 of the semiconductor layer sequence 1, for example, is again made of glass. In this example, however, cooling element 3 is a very thin layer of glass with a thickness of, for example, at most 50 μm. Such a thin glass layer 3, for example, is not self-supporting and thus does not contribute to the mechanical stabilization of the semiconductor chip 100. The thin glass layer 3 can, for example, be applied by a vapor deposition process.

In the examples shown so far, a mesa structure was provided in the edge region of each semiconductor chip 100, in which the semiconductor layer sequence 1 was removed starting from the back side 12 into the second semiconductor layer 14 and the resulting mesa trench was encapsulated by an insulation layer. Since the mesa trenches did not reach into the first layer 13, electromagnetic radiation can emerge laterally from the first layer 13 in these examples.

To increase light decoupling efficiency, FIG. 2E shows an example of a semiconductor chip 100 in which the lateral mesa trenches extend completely from the back side 12 through the second semiconductor layer 14, the active layer 10 into the first layer 13. Preferably, the mesa trenches also completely penetrate the first layer 13. In this way a lateral light extraction from the first layer 13 can be suppressed. Almost all of the light is then emitted from the semiconductor chip 100 via the front side 11 or the radiolucent cooling element 3.

Our chips and methods are not limited by the description in conjunction with the examples. Rather, this disclosure comprises any new feature as well as any combination of features, particularly including any combination of features in the appended claims, even if the feature or combination per se is not explicitly stated in the claims or examples.

This application claims priority of DE 10 2017 109 485.7, the subject matter of which is incorporated herein by reference.

1.-19. (canceled)

20. An optoelectronic semiconductor chip comprising:
a semiconductor layer sequence having an active layer that generates electromagnetic radiation,
two contact elements on a back side of the semiconductor layer sequence,
a radiolucent cooling element on a front side of the semiconductor layer sequence opposite the back side, and
a siloxane-containing converter layer between the cooling element and the semiconductor layer sequence, wherein
the contact elements are configured for electrical contacting of the semiconductor chip and are exposed in the unmounted state of the semiconductor chip,
the cooling element is different from a growth substrate of the semiconductor layer sequence, and
the cooling element has a thermal conductivity of at least 0.7 W/(m·K).

21. The semiconductor chip according to claim 20, wherein the cooling element comprises glass or consists of glass.

22. The semiconductor chip according to claim 20, wherein
the cooling element is self-supporting, and
the thickness of the cooling element is at least 250 μm.

23. The semiconductor chip according to claim 22, wherein a distance between the back side of the semiconductor layer sequence and sides of the contact elements exposed in the unmounted state is at most 5 μm.

24. The semiconductor chip according to claim 20, further comprising a carrier arranged on the back side of the semiconductor layer sequence.

25. The semiconductor chip according to claim 24, wherein a thickness of the cooling element is at most 100 μm.

26. The semiconductor chip according to claim 20, wherein the contact elements have a thickness of at least 100 μm.

27. The semiconductor chip according to claim 20, wherein the cooling element forms a radiation exit surface of the semiconductor chip.

28. The semiconductor chip according to claim 20, wherein the converter layer comprises or consists of a silicone matrix having converter particles embedded therein.

29. The semiconductor chip according to claim 20, further comprising a radiolucent adhesive layer arranged between the converter layer and the cooling element.

30. The semiconductor chip according to claim 20, wherein the converter layer is in direct contact with the cooling element.

31. The semiconductor chip according to claim 20, wherein the semiconductor layer sequence is structured at the front side.

32. The semiconductor chip according to claim 20, wherein the contact elements are laterally partially or completely surrounded by a potting.

33. The semiconductor chip according to claim 20, wherein the cooling element has one or more functional layers.

34. A method of manufacturing an optoelectronic semiconductor chip comprising:
A) growing a semiconductor layer sequence having an active layer on a growth substrate;
B) applying contact elements to a back side of the semiconductor layer sequence facing away from the growth substrate;
C) depositing the semiconductor layer sequence on an auxiliary carrier;
D) removing the growth substrate;
E) applying a converter layer to a front side of the semiconductor layer sequence opposite the back side, wherein the converter layer comprises siloxane;
F) applying a radiolucent cooling element to the front side of the semiconductor layer sequence, wherein the cooling element has a thermal conductivity of at least 0.7 W/(m·K); and
G) removing the auxiliary carrier.

35. The method according to claim 34, wherein A) to G) are performed in the specified order.

36. The method according to claim 34, wherein the converter layer is applied by spray coating.

37. The method according to claim 34, wherein the cooling element is applied to an undried converter layer and the converter layer serves as an adhesive for the cooling element.

38. The method according to claim 34, wherein the cooling element is a glass layer applied by evaporation.

39. An optoelectronic semiconductor chip comprising:
a semiconductor layer sequence having an active layer that generates electromagnetic radiation,
two contact elements on a back side of the semiconductor layer sequence,
a radiolucent cooling element on a front side of the semiconductor layer sequence opposite the back side, and
a siloxane-containing converter layer between the cooling element and the semiconductor layer sequence, wherein
the contact elements are configured for electrical contacting of the semiconductor chip and are exposed in the unmounted state of the semiconductor chip,
the cooling element is different from a growth substrate of the semiconductor layer sequence,
the cooling element has a thermal conductivity of at least 0.7 W/(m·K), and
the cooling element is self-supporting.
